(19) United States
(12) Patent Application Publication
(10) Pub. No.: US 2017/0345900 A1
(43) Pub. Date: Nov. 30, 2017

(54) DIFFUSION TOLERANT III-V SEMICONDUCTOR HETEROSTRUCTURES AND DEVICES INCLUDING THE SAME

(71) Applicant: Intel Corporation, Santa Clara, CA (US)

(72) Inventors: HAROLD W. KENNEL, Portland, OR (US); MATTHEW V. METZ, Portland, OR (US); WILLY RACHMADY, Beaverton, OR (US); GILBERT DEWEY, Hillsboro, OR (US); CHANDRA S. MOHAPATRA, Hillsboro, OR (US); ANAND S. MURTHY, Portland, OR (US); JACK T. KAVALIEROS, Portland, OR (US); TAHIR GHANI, Portland, OR (US)

(73) Assignee: Intel Corporation, Santa Clara, CA (US)

(21) Appl. No.: 15/527,221

(22) PCT Filed: Dec. 23, 2014
(86) PCT No.: PCT/US2014/072213

§ 371 Date: May 16, 2017

(51) Int. Cl. H01L 29/205; H01L 21/02; H01L 21/18

(52) U.S. Cl. CPC H01L 29/205; H01L 21/185; H01L 21/02576; H01L 21/02579; H01L 21/182

(57) ABSTRACT

Semiconductor devices including a subfin including a first III-V compound semiconductor and a channel including a second III-V compound semiconductor are described. In some embodiments the semiconductor devices include a substrate including a trench defined by at least two trench sidewalls, wherein the first III-V compound semiconductor is deposited on the substrate within the trench and the second III-V compound semiconductor is epitaxially grown on the first III-V compound semiconductor. In some embodiments, a conduction band offset between the first III-V compound semiconductor and the second III-V compound semiconductor is greater than or equal to about 0.3 electron volts. Methods of making such semiconductor devices and computing devices including such semiconductor devices are also described.

### FIELD

The present disclosure relates to diffusion tolerant III-V semiconductor heterostructures and devices including the same. Method of manufacturing such heterostructures and such devices are also described.

### BACKGROUND

Transistors and other semiconductor devices may be fabricated through a number of subtractive and additive processes. Certain benefits, such as channel mobility for transistors, may be obtained by forming the device layers in semiconductor material other than silicon, such as germanium and III-V materials. Where a crystalline material such as silicon serves as a starting material, epitaxial growth techniques (e.g., hetero-epitaxy) may be utilized to additively form a transistor channel including non-silicon materials on the substrate. Such processes can be challenging for a number of reasons, including but not limited to mismatch between the lattice constants and/or thermal properties of the substrate and the layers epitaxially grown thereon.

Manufacturers of silicon-based field effect transistor (FET) devices have now commercialized devices employing non-planar transistors. Such devices may include a silicon fin that protrudes from a substrate and includes a subfin region (e.g., at least a portion of which is below the surface of a trench dielectric) and an overlying channel. Such devices may also include one or more gate electrodes (hereinafter, “gate” or “gates”) that wrap around two, three, or even all sides of the channel (e.g., dual-gate, tri-gate, nanowire transistors, etc.). On either side of the gate, source and drain regions are formed in the channel or are grown in such a way as to be coupled to the channel. In any case, these non-planar transistor designs often exhibit significantly improved channel control as well as improved electrical performance (e.g., improved short channel effects, reduced short-to-drain resistance, etc.), relative to planar transistors.

With the foregoing in mind, performance of non-planar single or multi-gate transistors can be improved by the implementation of epitaxially grown heterostructures that include at least two materials with different band gaps, wherein one of the materials is a P-type semiconductor and the other is an N-type semiconductor. Although such devices have shown potential, they may suffer from one or more drawbacks that may limit their usefulness. For example, in instances where a heterostructure is used to form subfin and channel regions of a non-planar device such as a non-planar transistor, diffusion of dopants from the channel region to an underlying subfin region may cause the N-P junction of the heterostructure to move. This may result in the leakage or carriers from the channel region into the subfin region (i.e., subfin leakage), which may hinder the ability of a gate to turn the non-planar transistor OFF.

### BRIEF DESCRIPTION OF THE DRAWINGS

Features and advantages of embodiments of the claimed subject matter will become apparent as the following Detailed Description proceeds, and upon reference to the Drawings, wherein like numerals depict like parts, and in which:

FIG. 1 is a cross sectional view of one example of a diffusion tolerant III-V semiconductor heterostructure consistent with the present disclosure.

FIG. 2A is a perspective view of one example of a non-planar transistor including a diffusion tolerant III-V semiconductor heterostructure consistent with the present disclosure.

FIG. 2B is a cross sectional view of the example non-planar transistor of FIG. 2A along axis A.

FIG. 2C is a cross sectional view of the example non-planar transistor of FIG. 2A along axis B.

FIG. 3 is a flow chart of example operations of a method of forming a non-planar transistor including a semiconductor heterostructure consistent with the present disclosure.

FIGS. 4A-4I stepwise illustrate the formation of one example of a non-planar transistor including a semiconductor heterostructure consistent with the present disclosure.

FIG. 5 depicts one example of a computing system with one or more components that include a diffusion tolerant III-V heterostructure consistent with the present disclosure.

Although the following Detailed Description will proceed with reference being made to illustrative embodiments, many alternatives, modifications, and variations thereof will be apparent to those skilled in the art.

### DETAILED DESCRIPTION

The terms “over,” “under,” between,” and “on,” are often used herein to refer to a relative position of one material layer or component with respect to other material layers or components. For example, one layer disposed on (e.g., over or above) or under (below) another layer may be directly in contact with the other layer, or may have one or more intervening layers. Moreover one layer disposed between two other layers may be directly in contact with the two other layers or may be separated by one or more of the other layers, e.g., by one or more intervening layers. Similarly unless expressly indicated to the contrary, one feature that is adjacent to another feature may be in direct contact with the adjacent feature, or may be separated from the adjacent feature by one or more intervening features. In contrast, the terms “directly on” or “directly below” are used to denote that one material layer is in direct contact with an upper surface or a lower surface, respectively, of another material layer. Likewise, the term “directly adjacent” means that two features are in direct contact with one another.

As noted in the background, semiconductor hetero structures have been investigated for use in the production of various portions of semiconductor devices such as non-planar single and multi-gate transistors. For example, various semiconductor heterostructures have been investigated for use in the formation of subfin and channel regions of the channel of fin based field effect transistors, also referred to herein as FINFETS. In such devices, the channel may include one or more layers of a first compound semiconductor that are deposited within a trench, e.g., to form a subfin region of the channel. The channel may also include one or more layers of a second compound semiconductor may then be deposited on the layer(s) of first compound semiconductor, e.g., to form a channel region, also referred to herein as an “active region” of the channel.

The layer(s) of the first compound semiconductor forming the subfin region may be of one type (e.g., N or P-type) semiconductor, whereas the layer(s) of the second compound semiconductor forming the active region may be of the opposite type (e.g., P or N-type) from the first compound semiconductor. That is, where the layer(s) forming the channel region are a P-type intrinsic or extrinsic semiconductor, the layer(s) forming the subfin region may be an N-type intrinsic or extrinsic semiconductor, and vice versa. As such, an N-P or P-N junction may be formed between the subfin and active regions of the channel. Portions of the active region may be doped with p-type (acceptors) or n-type (donors) dopants to form a source and drain, and a gate stack may be formed on at least a part of the channel. The gate stack may include a gate electrode that is configured to modulate the operation of the device, i.e., to turn the device ON or OFF.

With the foregoing in mind, in instances where one or more of the layers is doped with one or more donors or acceptors, diffusion of the dopant(s) may occur as the heterostructure is formed (e.g., during one or more annealing steps) and/or as the heterostructure is used in a device. That is, dopants within the N-type layer(s) of the heterostructure may diffuse into adjacent (e.g., over or underlying) P-type layers, and vice versa. Due to differences in diffusion rates and other factors, dopant diffusion may cause the location of the junction in the structure to move and/or to become less distinct. This may present difficulties when such heterostructures are used in semiconductor devices, such as but not limited to fin based field effect transistors (FINFETS). Indeed in instances where such a heterostructure is used to form all or a part of a channel of a FINFET, dopant diffusion can cause the junction of the heterostructure to migrate below the gate, potentially resulting in subfin leakage. As noted above this may hinder the ability of the gate to turn the transistor OFF.

With the foregoing in mind, one aspect of the present disclosure relates to III-V heterostructures wherein at least one layer of the heterostructure has been doped N or P-type with an amphoteric dopant. As used herein, the term “amphoteric dopant” is used to reference a dopant that acts as a donor (n-type) in one layer of the heterojunction (e.g., an N-type layer), but acts as an acceptor (p-type) in another material layer of the heterojunction (e.g., a P-type layer). As will become clear from the following discussion, use of the amphoteric dopants can alleviate or even eliminate migration of the N-P junction in such structures that is attributable to dopant diffusion. Consequently, the heterostructures described herein may be advantageously used to form various components of semiconductor devices, such as but not limited to a channel of a non-planar transistor.

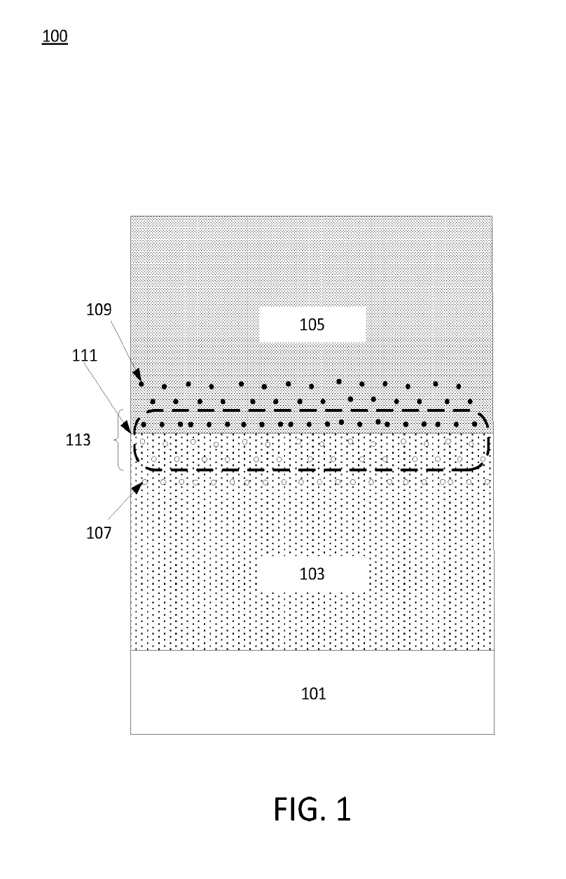

Reference is therefore made to FIG. 1, which depicts a cross sectional view of one example of a semiconductor heterostructure consistent with the present disclosure. As shown, heterostructure 100 includes substrate 101, a layer 103 of a first compound semiconductor material formed on substrate 101, and a layer 105 of a second compound semiconductor material formed on layer 103.

Substrate 101 may be formed of any material that is suitable for use as a substrate of a semiconductor heterostructure or device, and in particular as a substrate for non-planar transistors such as FINFETS and multi-gate transistors. Non-limiting examples of suitable materials that may be used as substrate 101 therefore include silicon (Si), germanium (Ge), silicon-germanium (SiGe), silicon-carbide (SiC), sapphire, a III-V compound semiconductor, a silicon on insulator (SOI) substrate, combinations thereof, and the like. Without limitation, in some embodiments substrate 101 is formed from or includes single crystal silicon.

In some embodiments one or more underlayers (not illustrated) may be deposited on substrate 101, e.g., such that they are present between substrate 101 and layer 103. For example, one or more semiconductor base layers may be deposited on substrate 101. When used, such base layers may be pseudomorphic, metamorphic, or substantially lattice matched buffer and/or transition layers, as understood in the art. In any case, substrate 101 in some embodiments may be configured to provide an epitaxial seeding surface (e.g., a crystalline surface having a (100) orientation) for the subsequent deposition of the materials of layer 103. Of course, substrates with other crystalline orientations may also be used.

Layer 103 may be formed of any suitable semiconductor material, and in particular semiconductor materials that are suitable for use in forming a subfin region of a channel of non-planar semiconductor device, such but not limited to FINFETs and single and multi-gated non-planar transistors. In particular, layer 103 may be formed from one or more III-V compound semiconductors. More specifically, layer 103 may be formed from one or more layers of semi conductive material that include at least one element from group III of the periodic table (e.g., Al, Ga, In, etc.) and at least one element of group V of the periodic table (e.g., N, P, As, Sb, etc.). Layer 103 may therefore be formed from a binary, ternary, or even quaternary III-V compound semiconductor that includes two, three, or even four elements from groups III and V of the periodic table. Examples of suitable III-V compound semiconductors that may be used in layer 103 include but are not limited to GaAs, InP, InSb, InAs, GaP, GaN, GaSb, GaAsSb, InAlAs, AlAs, AlP, AlSb, alloys or combinations thereof, and the like. Without limitation, in some embodiments layer 103 includes or is formed from one or more of N or P-type GaSb, GaAsSb or InAlAs. As discussed below, in some embodiments layer 103 includes GaSb, GaAsSb, or InAlAs or a combination thereof, all or a portion of which has been doped P-type with one or more amphoteric dopants.

Layer 103 may be formed on substrate 101 (or a layer deposited thereon) using any suitable process. For example, layer 103 may be formed by depositing one or more layers of a III-V semiconductor on substrate 101 using an additive deposition process such as chemical vapor deposition, plasma enhanced chemical vapor deposition (PECVD), metal organic chemical vapor deposition (MOCVD), atomic layer deposition, combinations thereof, and the like.

Layer 105 may be formed of any suitable semiconductor material, and in particular semiconductor materials that are suitable for use in forming an active region of the channel of a non-planar semiconductor device, such but not limited to FINFETs and single and multi-gated non-planar transistors. In particular, layer 105 may be formed from one or more III-V compound semiconductors. Thus like layer 103, layer 105 may be formed from one or more layers of semi conductive material that includes at least one element from group III of the periodic table (e.g., Al, Ga, In, etc.) and least one element of group V of the periodic table (e.g., N, P, As, Sb, etc.). Layer 105 may therefore be formed from a binary, ternary, or even quaternary III-V compound semiconductor that includes two, three, or even four elements from groups III and V of the periodic table. Without limitation, layer 105 in some embodiments is formed from at least one III-V semiconductor that is different from the III-V semiconductor(s) used in layer 103.

Examples of suitable III-V compound semiconductors that may be used in layer 105 include but are not limited to InₓGa₁₋ₓAs (where x is the mole fraction of In and may range, for example, from ≧about 0.2, such as from ≧about 0.3, or even ≧about 0.6) GaAs, InSb, InAs, IN-P, GaP, GaN, GaSb, GaAsSb, InAlAs, combinations thereof, and the like. Without limitation, in some embodiments layer 105 includes or is formed from one or more of N or P-type InₓGa₁₋ₓAs (e.g., where x is ≧about 0.2, about ≧about 0.3 or even ≧about 0.6), InSb, or InAs. As discussed below, in some embodiments layer 105 includes InₓGa₁₋ₓAs, InSb, InAs or a combination thereof, all or a portion of which has been doped N-type with one or more amphoteric dopants.

Layer 105 may be formed on layer 103 (or a layer deposited thereon) using any suitable process. For example, layer 105 may be formed by depositing one or more layers of a III-V semiconductor on layer 103 using an additive deposition process such as chemical vapor deposition, plasma enhanced chemical vapor deposition (PECVD), metal organic chemical vapor deposition (MOCVD), atomic layer deposition, combinations thereof, and the like.

Consistent with the foregoing discussion, in some embodiments a combination of first and second III-V compound semiconductors may be selected for use in forming layer 103 and layer 105, e.g., to attain certain desired properties. With this in mind, in some embodiments layer 103 may be formed from or include one or more layers of N or P-type GaSb, GaAsSb or InAlAs, and layer 105 may be formed from one or more layers of N or P-type InₓGa₁₋ₓAs, InSb, or InAs.

One or both of layers 103 and 105 may be doped with an amphoteric dopant, e.g., to adjust the relative number of carriers and holes contained therein. This concept is illustrated in FIG. 1, which depicts layer 103 as including dopant(s) 107 and layer 105 as containing dopant(s) 109. In this regard, dopants 107 and 109 may be selected from amphoteric dopants. That is, dopant 107 may be selected from dopants that are N or P-type dopants in layer 103, but which are of the opposite type in layer 105. Thus for example, where dopant 107 is an N-type dopant (e.g., donor) in layer 103, it may be a P-type dopant (acceptor) in layer 105. Likewise where dopant 107 is a P-type (acceptor) dopant in layer 103, it may be an N-type (donor) dopant in layer 105. Likewise, dopant 109 dopants that are donors or acceptors in layer 105, but which are of the opposite type in layer 103. Non-limiting examples of suitable amphoteric dopants include but are not limited to elements in group IV of the periodic table, e.g., C, Si, Ge, Sn, combinations thereof, and the like.

Without wishing to be bound by theory, Applicant believes that the amphoteric nature of the dopants described herein may be attributable to their incorporation in either the group III or group V sublattice of the III-V semiconductor materials used in layers 103 and 105. More specifically, when dopant's 107, 109 occupy the group III sublattice of a III-V semiconductor they may act as donor (N-type), but when they occupy the group V sublattice of such materials they may act as acceptors (P-type). In this regard, although growth conditions such as the amount of group V precursors during the formation of layers 103, 105, it is noted that strong thermodynamic factors often dictate whether a particular dopant will be incorporated in the group III sublattice or the group V sublattice.

Doping of layers 103, 105 may be performed using any suitable doping process, including those understood in the art. Moreover it should be understood that while FIG. 1 depicts an embodiment in which layers 103 and 105 include a relatively uniform distribution of dopants 107, 109 in corresponding portions thereof, such distribution is for the sake of example only and any suitable dopant distribution and concentration may be employed.

As further shown in FIG. 1, heterostructure 100 includes junction 111, which may be located at an interface between layers 103 and 105. Depending on the nature of layers 103 and 105, junction 100 may be in the form of an N-P or P-N junction. With this in mind, as layers 103 and 105 are formed, annealing or other processing steps may induce movement (e.g., diffusion) of dopants 107, 109 across junction 111, e.g., within region 113. Because dopants 107 and 109 are amphoteric dopants however, their diffusion across junction 111 may not affect or may not substantially affect the location of junction 111. That is when dopants 107, 109 diffuse across junction 111 (during the formation of heterojunction 100 or at another time), the location of junction 111 may remain substantially the same, e.g., at the interface between layer 103 and 105.

As may be appreciated, the location of junction 111 may remain the same or substantially the same due to the amphoteric nature of dopants 107, 109. That for example, if dopants 107 are P-type) dopants in layer 103, when they diffuse across junction 111 they become N-type dopants in layer 105. Likewise if dopants 109 are N-type in layer 105, when they diffuse across junction 111 they become P-type dopants in layer 103. As such, the location of the P-N or N-P junction 111 may remain the same or substantially the same.

With the foregoing in mind, in some embodiments layer 103 is formed from one or more layers of GaSb or GaAsSb that has been doped P-type with an amphoteric dopant (e.g., dopant 107 is Si, Ge, etc.), and layer 105 is formed from one or more layers of InGaAs or InAs that has been doped N-type with the same amphoteric dopant (i.e., Si, Ge, etc.). In other embodiments layer 103 is formed from one or more layers of InAlAs that has been doped P-type with an amphoteric dopant (e.g., C), whereas layer 105 is formed from one or more layers of InₓGa₁₋ₓAs or InAs that has been doped N-type with the same amphoteric dopant (i.e., C). Still further, in some embodiments layer 103 is formed from one or more layers of GaSb, AlSb, or GaAlSb that has been doped P-type with an amphoteric dopant (e.g., Si, C, Sn, Ge, etc.), and layer 105 is formed from one or more layers of InSb or InAs doped N-type with the same amphoteric dopant (i.e., Si, C, Sn, Ge, etc.). In any of such embodiments, it may be understood that the amphoteric dopant acts as an acceptor in layer 103, whereas it acts as an donor in layer 105.

In some embodiments layers 103 and 105 may be formed from or include first and second III-V compound semiconductors, respectively, which are chosen such that the layer 105 may be hetero-epitaxially grown on layer 103. The first and second III-V compound semiconductors may therefore be selected based at least in part on the relative differences between their respective lattice parameters. In some embodiments, the first and second III-V compound semiconductors may be substantially lattice matched, i.e., the difference between their respective lattice parameters may be sufficiently low as to enable hetero-epitaxial growth of a layer (e.g., layer 105) of the second III-V compound semiconductor on a layer (e.g., layer 103) of the first III-V compound semiconductor. As used herein, the term “substantially lattice matched” means that the relative difference between corresponding lattice parameters of two III-V compound semiconductors is supportive of epitaxial growth and does not substantially impact the properties of the heterojunction. In some embodiments, substantially lattice matched means that the relative difference between such lattice parameters is less than or equal to about 5%, or even less than or equal to about 1%. In this regard, non-limiting examples of first and second III-V semiconductors that are substantially lattice matched and may be used in layers 103 and 105 include those enumerated in the example embodiments discussed above.

It is noted that FIG. 1 depicts an embodiment in which layer 103 is a single layer of a first III-V compound semiconductor and layer 105 is a single layer of a second III-V compound semiconductor that is formed directly on layer 103 (i.e., on an upper surface of the layer of first III-V compound semiconductor). It should be understood that such configuration is for the sake of example only, and that other configurations are possible. Indeed the present disclosure envisions embodiments in which one or more of layers 103, 105 include a plurality of layers (e.g., of III-V compound semiconductor(s)), which may be the same or different with regard to composition, dopant, dopant distribution, dopant concentration, combinations thereof, and the like.

As may be appreciated from the foregoing, the heterostructures described herein may be tolerant to the diffusion of dopants across a junction thereof, e.g., due to the amphoteric nature of such dopants. As will be described in detail below, such structures may be advantageously used to form various components of a semiconductor device, including but not limited to the channel of a non-planar transistor such as a FINFET and/or a single multi-gate transistor.

With the foregoing in mind, another aspect of the present disclosure relates to semiconductor devices that include a diffusion tolerant heterostructure consistent with the present disclosure. In this regard, the inventors have conducted an investigation into the use of diffusion tolerant heterostructures to form the subfin and active (e.g., channel) regions of a fin-based semiconductor device, such as FINFET or other non-planar transistor. In such devices one or more layers of a first III-V compound semiconductor may be deposited within a trench, e.g., to form a subfin region. One or more layers of a second III-V compound semiconductor may then be deposited on the layer(s) of first III-V compound semiconductor, e.g., to form an active (channel) region of the device. All or a portions of the layers forming the subfin region may be doped N or P with an amphoteric dopant. Likewise, portions of the channel region may be doped with the same amphoteric dopant to form a source and a drain. A gate stack may be formed on at least a part of the channel. The gate stack may include a gate electrode that is configured to modulate the operation of the device, i.e., to turn the device ON or OFF.

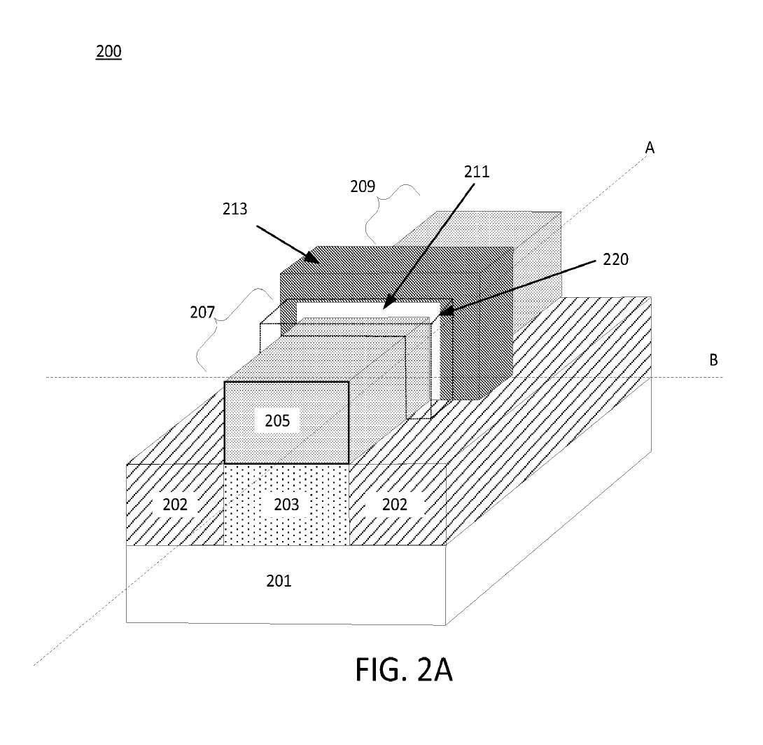

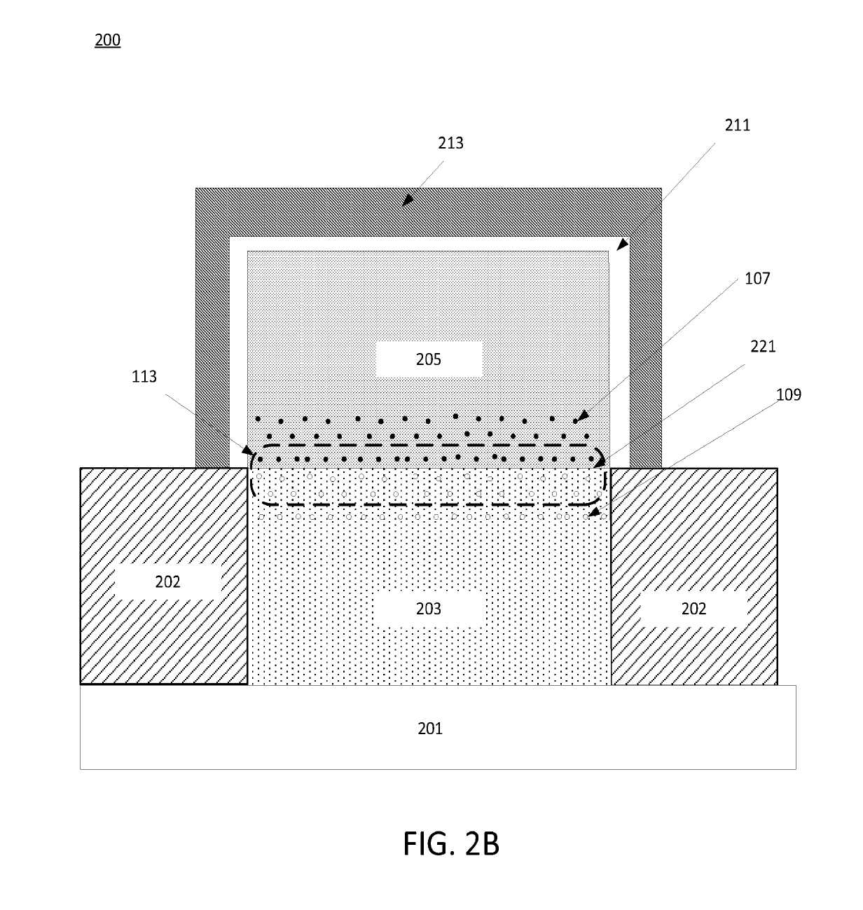

As one example of the structure of such devices reference is made to FIGS. 2A to 2C. FIG. 2A is a perspective view of a non-planar semiconductor device, in this case of one portion of a non-planar semiconductor device 200 (device 200). FIGS. 2B and 2C are cross sectional views of device 200 along axes A and B, respectively. As shown, device 200 includes a substrate 201, trench dielectric 202, a subfin region 203, and a channel region 205. A gate stack (e.g., formed by gate dielectric 111 and gate electrode 213) may be formed over the channel region 205, resulting in the production of a non-planar semiconductor device 200, e.g., a FINFET.

It is noted that for the sake of illustration, the present disclosure focuses on and many of the FIGS. depict example use cases in which a diffusion tolerant III-V heterostructure is used to form a subfin region and a channel region of a non-planar semiconductor device such as a FINFET, a multi-gate (e.g., double gate, tri-gate, etc.) transistor, or the like. It should be understood that such discussion is for the sake of example only, and the technologies described herein may be extended to other use cases (e.g., other semiconductor devices) as may be appropriate and appreciated by one of ordinary skill in the art.

With the foregoing in mind, the inventors have determined that by forming subfin region 203 and channel 205 with a diffusion tolerant III-V heterostructure (as discussed above), the (N-P or P-N) the location of the junction between subfin region 203 and 205 may become tolerant to the diffusion of (amphoteric) dopants between such layers. As a result, the location of the junction between subfin region 203 and channel region 205 may be sharply defined and positioned at the interface between such regions. Moreover, the location of the junction may not move in response to diffusion of dopants from subfin region 203 to channel region 205, and vice versa. As may be appreciated, this can avoid downward movement of the junction (i.e., movement into subfin region 203), thus limiting or even avoiding the generation of subfin leakage attributable to dopant diffusion.

Returning to FIGS. 2A-2C, substrate 201 may be formed of any material that is suitable for use as a substrate of a semiconductor device, and in particular as a substrate for non-planar transistors such as FINFETS and multi-gate transistors. Non-limiting examples of suitable materials include those mentioned above for substrate 101 in connection with FIG. 1, which for the sake of brevity are not reiterated. Without limitation, in some embodiments substrate 201 is formed from or includes single crystal silicon.

Consistent with the description of FIG. 1 above, in some embodiments one or more underlayers (not illustrated) may be deposited on substrate 201, e.g., such that they are present between substrate 201 and one or more of trench dielectric 202 and the layer(s) of III-V semiconductor materials forming subfin region 203. For example, one or more semiconductor base layers may be deposited on substrate 201. When used, such base layers may be pseudomorphic, metamorphic, or substantially lattice matched buffer and/or transition layers, as understood in the art. In any case, substrate 201 may be understood to provide an epitaxial seeding surface (e.g., a crystalline surface having a (100) orientation) for the subsequent deposition of the layer(s) of III-V semiconductor materials of subfin region 203.

In the embodiment of FIG. 2A, a trench (not separately labeled) is defined by the sidewalls of trench dielectric 202 (hereinafter, trench sidewalls) and an upper portion of substrate 201. Thus in this example embodiment, a trench is defined by at least two trench sidewalls (of trench dielectric 202) and an upper surface of substrate 201.

The dimensions of the trench may vary widely, and a trench of any suitable dimension may be used. Without limitation, in some embodiments the height and width of the trenches described herein are selected so as to enable the deposition of the materials used to form subfin region 203 and/or channel region 205 via an aspect ratio trapping (ART) process. Accordingly, in some embodiments the width of the trenches described herein may range from about greater than 0 to about 500 nanometers (nm), such as greater than 0 to about 300 nm, greater than 0 to about 100 nm, about 5 to about 100 nm, or even about 5 to about 30 nm. Likewise the height of the trenches may vary widely and may range, for example, from greater than 0 to about 500 nm, such as about 100 to about 300 nm.

Trench dielectric 202 may be formed from any material that is suitable for use as a trench dielectric material of a non-planar semiconductor device. Non-limiting examples of such materials include oxides, nitrides and alloys, such as but not limited to silicon oxide (SiO₂), silicon nitride (SiN), combinations thereof, and the like. Without limitation, in some embodiments trench dielectric 202 is SiO₂.

Trench dielectric 202 may be formed in any suitable manner. For example, trench dielectric 202 may be formed by depositing one or more layers of dielectric material (e.g., SiO₂) on substrate 201, e.g., via chemical vapor deposition (CVD), plasma enhanced CVD, or another suitable deposition process. The resulting deposited layer may be planarized, and an etching process may be used to remove portions of the dielectric material so as to form a trench. Of course this process is for the sake of example only, and other processes may be used to form a trench consistent with the present disclosure. For example, a trench may be formed by etching substrate 101 to form one or more fins, depositing trench dielectric 202 around the fin, and removing the portion of substrate 201 forming the fin so as to form a trench bounded by trench dielectric 202 and an upper surface of substrate 201.

It should also be understood that the trenches described herein need not be formed on an upper surface of substrate 201, e.g., as shown in FIGS. 2A-2C. Indeed the present disclosure envisions embodiments in which a trench may be formed within substrate 201, e.g., via chemical etching or another suitable trench forming process. In such instances, one or more trench dielectric materials such as SiO₂, TiN, etc. may be selectively deposited within the trench, e.g., on the sidewalls thereof. One or more material layers of subfin region 203 and/or channel region 205 may then be deposited within the trench.

In more general terms, in some embodiments the non-planar semiconductor devices described herein may include a substrate and at least one trench formed on or within the substrate. The trench may be defined by at least two opposing sides (trench sidewalls) and a bottom. The bottom of the trench may be in the form of an upper surface of the substrate, and/or one or more buffer and/or transition layers deposited on the substrate.

In any case, subfin region 203 of device 200 may be formed within the trench, and channel region 205 may be formed on subfin region 203. In general, subfin region 203 may include and/or be formed of one or more layers of a first III-V compound semiconductor and channel 205 may include and/or be formed from one or more layers of a second III-V compound semiconductor. As such, it may be understood that in some embodiments that one of more layers of the material(s) in subfin region 203 may be in direct contact with the upper surface of substrate 201 and the trench sidewalls, e.g., as shown in FIG. 2A. It should be understood however that this illustration is for the sake of example only, and that the materials of subfin region 203 need not be formed in direct contact with substrate 201 and the trench sidewalls.

Indeed the present disclosure envisions embodiments in which subfin region 203 is formed on the upper surface of substrate 201, e.g., wherein one or more layers (e.g., buffer layers, epitaxial seeding layers, etc.) are formed between the material(s) of subfin region 203 and substrate 201. Likewise the present disclosure envisions embodiments in which one or more layers (e.g., trench isolation oxide, etc.) are present between the trench sidewalls defined by trench dielectric 202 and subfin region 203. Without limitation, in some embodiments subfin region 203 is includes one or more layers of a first III-V compound semiconductor, wherein at least one layer of the first III-V compound semiconductor is in direct contact with an upper surface of substrate 201 and trench sidewalls defined by trench dielectric 202.

In some embodiments the first and second III-V compound semiconductors used in subfin region 203 and channel region 205 may be selected such that material layers of such regions are substantially lattice matched. For example in some embodiments the first and second III-V compound semiconductors may be selected such that a layer of the second III-V compound semiconductor is substantially lattice matched to an underlying layer of first III-V compound semiconductor. As a result, the layer of the second III-V compound semiconductor may be hetero-epitaxially grown on a layer of the first III-V compound semiconductor.

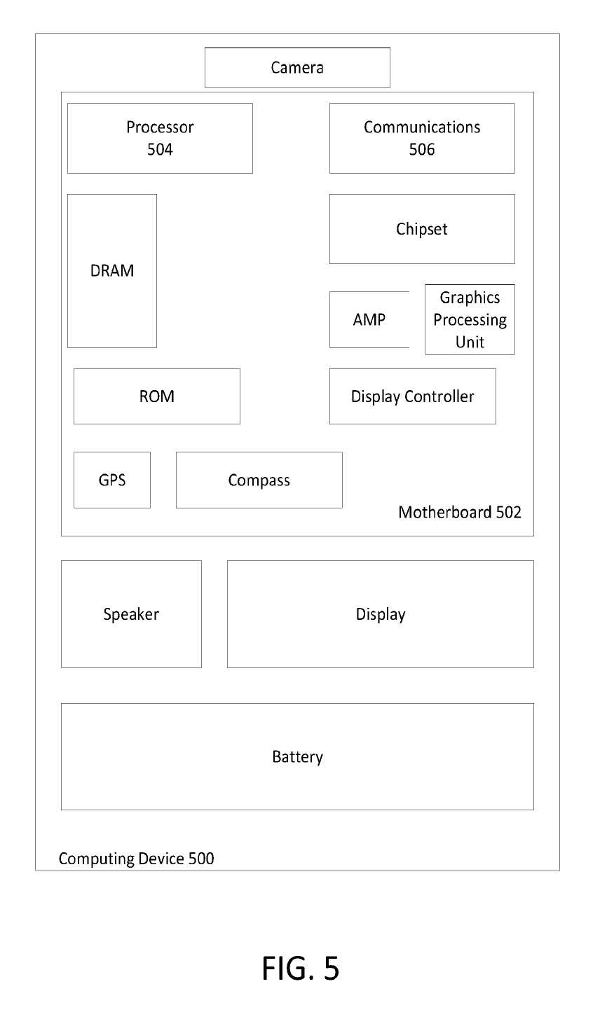

The present disclosure envisions a wide variety of first and second III-V compound semiconductors that may be used to form one or more layers of subfin region 203 and channel 205, respectively. In this regard, non-limiting examples of suitable III-V compound semiconductors that may be used to form subfin region 203 include the III-V compound semiconductors mentioned above with regard to layer 103 of FIG. 1. Likewise non-limiting examples of suitable III-V compound semiconductors that may be used to form channel region 205 include the III-V compound semiconductors mentioned above with regard to layer 105 of FIG. 5. Consistent with the foregoing discussion, one or more of the layers of III-V compound semiconductor forming subfin region 203 and channel region 205 may be doped with an amphoteric dopant, such as those described above. Without limitation, in some embodiments at least a portion of subfin region 203 is doped P-type with an amphoteric dopant, and at least a portion of channel region 205 is doped N-type with an amphoteric dopant that is the same or different from the amphoteric dopant used in subfin region 203. In other embodiments, at least a portion of subfin region 203 is doped N-type with an amphoteric dopant, and at least a portion of channel region 205 is doped P-type with an amphoteric dopant that is the same or different from the amphoteric dopant used in subfin region 203.

Regardless of the nature of the first and second III-V compound semiconductors, portions of the channel region 205 may be processed to form a source region 207 and a drain region 209, as best shown in FIGS. 2A and 2C. For example, in some embodiments source and drain regions 207, 209 may be formed by doping portions of a layer of the second III-V compound semiconductor in channel region 205 with one or more amphoteric dopants, such as those noted above.

In specific non-limiting embodiments subfin region 203 is formed from at least one layer of GaSb or GaAsSb that has been doped P-type with an amphoteric dopant (e.g., dopant 107 is Si, Ge, etc.), and channel region 205 is formed from at least one layer of InGaAs or InAs that has been source/drain doped N-type with the same amphoteric dopant (i.e., Si, Ge, etc.). In other embodiments subfin region 203 is formed from at least one layer of InAlAs that has been doped P-type with an amphoteric dopant (e.g., C), whereas channel region 205 is formed from at least one layer of InₓGa₁₋ₓAs or InAs that has been source/drain doped N-type with the same amphoteric dopant (i.e., C). Still further, in some embodiments subfin region 203 is formed from at least one layer of GaSb, AlSb, or GaAlSb that has been source/drain doped P-type with an amphoteric dopant (e.g., Si, C, Sn, Ge, etc.), and channel region 205 is formed from at least one layer of InSb or InAs doped N-type with the same amphoteric dopant (i.e., Si, C, Sn, Ge, etc.). In any of such embodiments, it may be understood that the amphoteric dopant acts as an acceptor in subfin region 103, whereas it acts as a donor in channel region 205.

The non-planar devices described herein may be constructed such that a boundary (heterojunction) between subfin region 203 and channel 205 may be located at a desired position. For example, in some embodiments the boundary between subfin region 203 and channel region 205 may be positioned at or near the base of channel region 205. In this regard it is noted that channel region 205 may have a height Hf, wherein the boundary between subfin region 203 and channel region 205 is located at the bottom of Hf.

Thus for example, as best shown in FIG. 2C a junction 221 may exist between channel region 205 and subfin region 203, e.g., in the vicinity of source 207 and drain 209. Consistent with the foregoing discussion of junction 111 in FIG. 1, junction 221 in FIG. 2C may be an N-P or P-N junction, depending on the nature of the materials forming subfin region 203 and channel region 205. Consistent with the foregoing discussion of FIG. 1, because channel region 205 and subfin region 203 are doped with an amphoteric dopant (e.g., dopants 107, 109), diffusion of such dopants across from subfin region 203 to channel region 205 and vice versa may not affect (or may not substantially affect) the location of junction 221. With this in mind, in some embodiments the position of junction 221 is preferably set at the interface between subfin region 203 and channel region 205, as shown in FIG. 2C. Without limitation, junction 221 in some embodiments is position at the interface of subfin and channel regions 203, 205, and at a height corresponding to the height of trench dielectric 202, as shown in FIG. 2C.

In some embodiments, the height of trench dielectric may be set such that an upper surface thereof is at the same or approximately the same height as the junction 221 between subfin region 203 and channel region 205, as also shown in FIGS. 2A-2C. Of course such illustrations are for the sake of example only, and the junction 221 between subfin region 203 and channel region 205, as well as the height of trench dielectric 202 may be configured in any suitable manner. For example in some embodiments the height of trench dielectric 202 may be such that the junction 221 between subfin region 203 and channel region 205 is above or below an upper surface of trench dielectric 202.

As also shown in FIGS. 2A-2C, a gate stack (not separately labeled) may be formed over at least part of an exposed portion of channel region 205. This concept is best shown in FIG. 2B, wherein a gate stack is formed over a portion of channel region 205 and includes a gate electrode 213 which is isolated from channel region 205 by gate dielectric 211. Gate electrode 213 and gate dielectric 211 may be formed of any suitable gate electrode and gate dielectric material, and thus the nature of such materials is not described for the sake of brevity. Likewise, gate electrode 213 may be electrically isolated from channel region 205 and, more particularly, from source and drain regions (207, 209), by gate spacer 220 (best shown in FIG. 2C). In some embodiments, gate electrode 213 may extend around channel region 205 and terminate at the interface between channel region 205 and subfin region 203, as shown in FIG. 2C.

It is noted that while FIGS. 2A-C depict embodiments in which source 207 and drain 209 are embedded in channel region 205, such configurations are not required and any suitable source/drain configuration may be employed. For example, the present disclosure envisions embodiments in which the non-planar semiconductor devices described herein utilize raised source and drain regions that may be grown on or otherwise coupled to channel region 205.

Although FIGS. 2A-C depict an embodiment in which gate electrode 213 and gate dielectric 211 are formed on three sides of channel region 205 (e.g., to form a triple gate transistor), it should be understood that such illustration is for the sake of example only, and that gate electrode 213 and/or gate dielectric 211 may be formed on one, two, three, or more sides of channel region 205. Thus for example, a gate stack may be formed over a portion of channel region 205 so as to form a single, double, or triple gated non-planar device, such as a single or multigate transistor. In some embodiments and as best shown in FIG. 2B, gate electrode 213 may extend from an upper surface of channel region 205 and down at least one side thereof, such that a bottom portion of gate electrode 213 is proximate or adjacent trench dielectric 102.

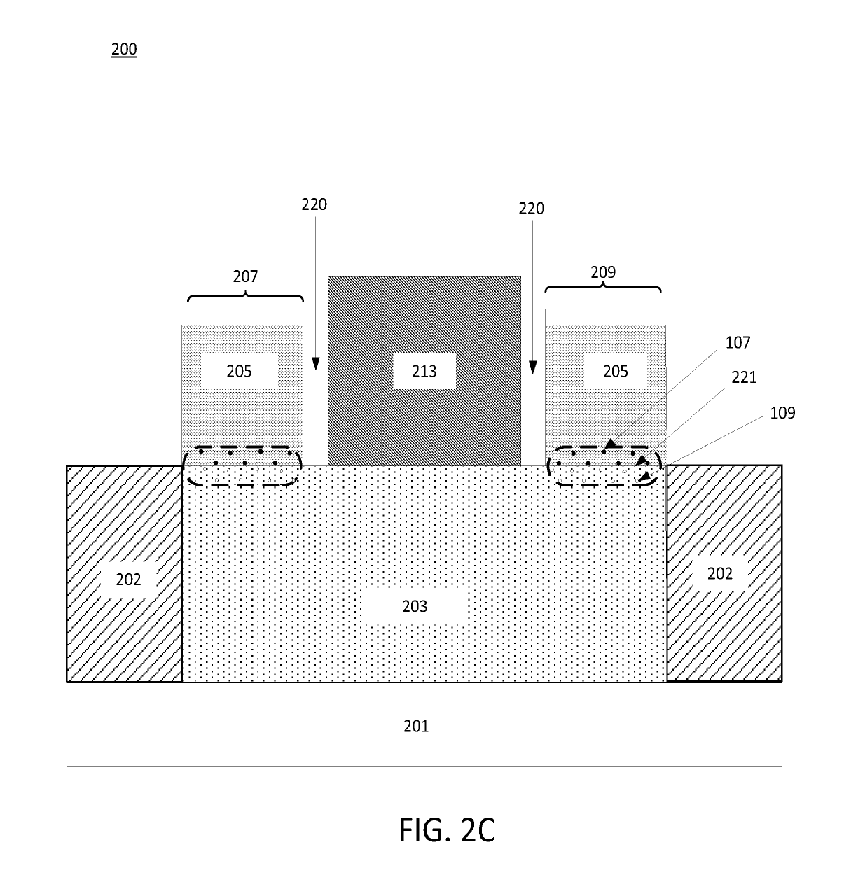

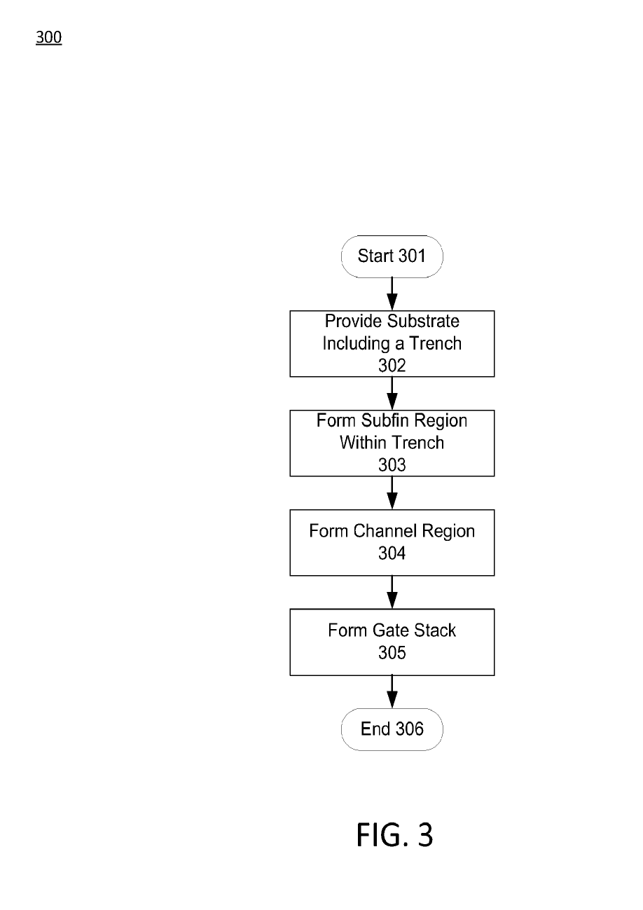

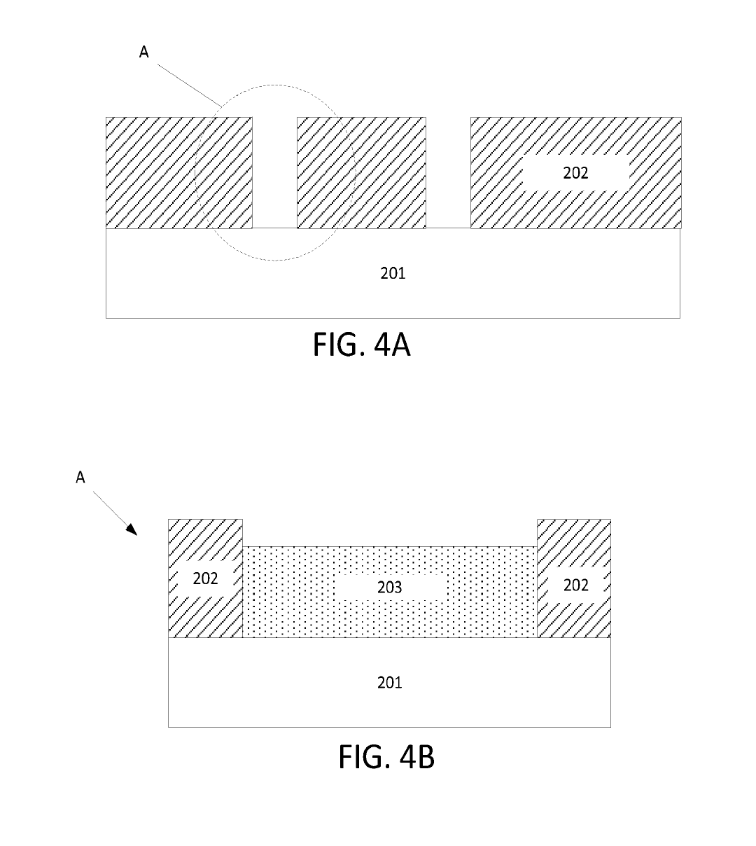

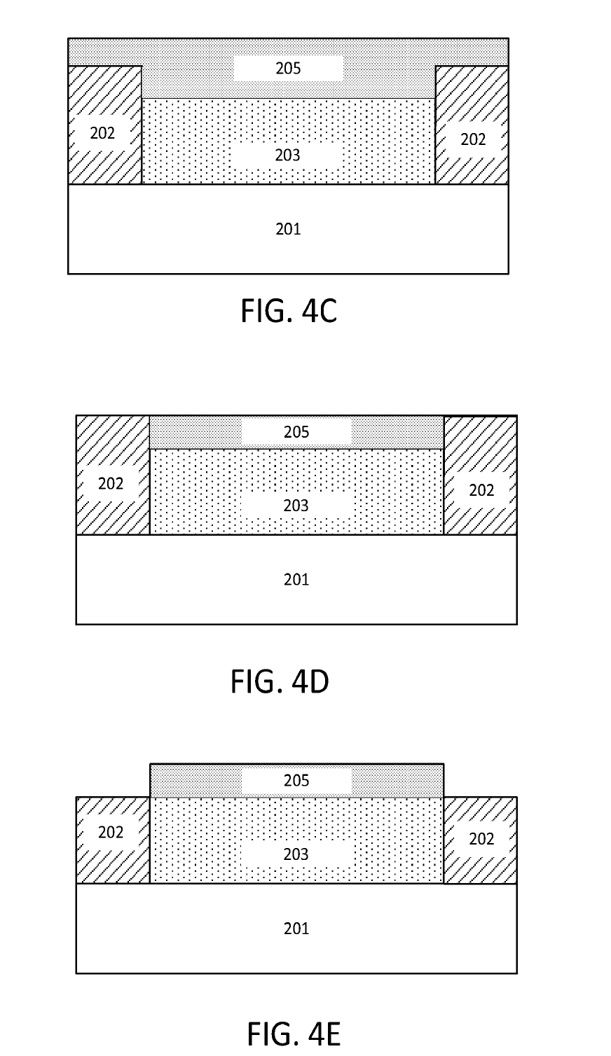

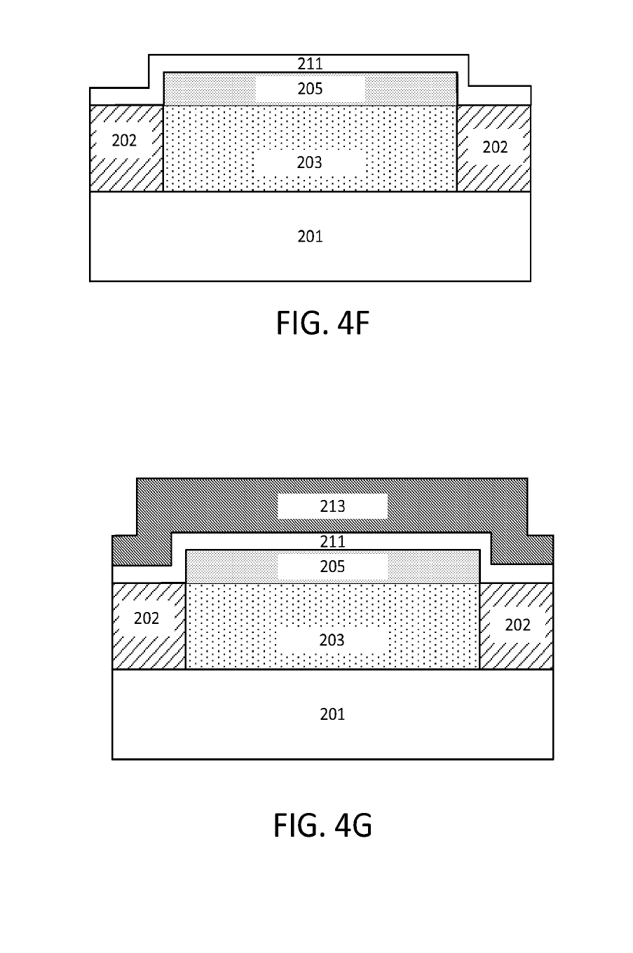

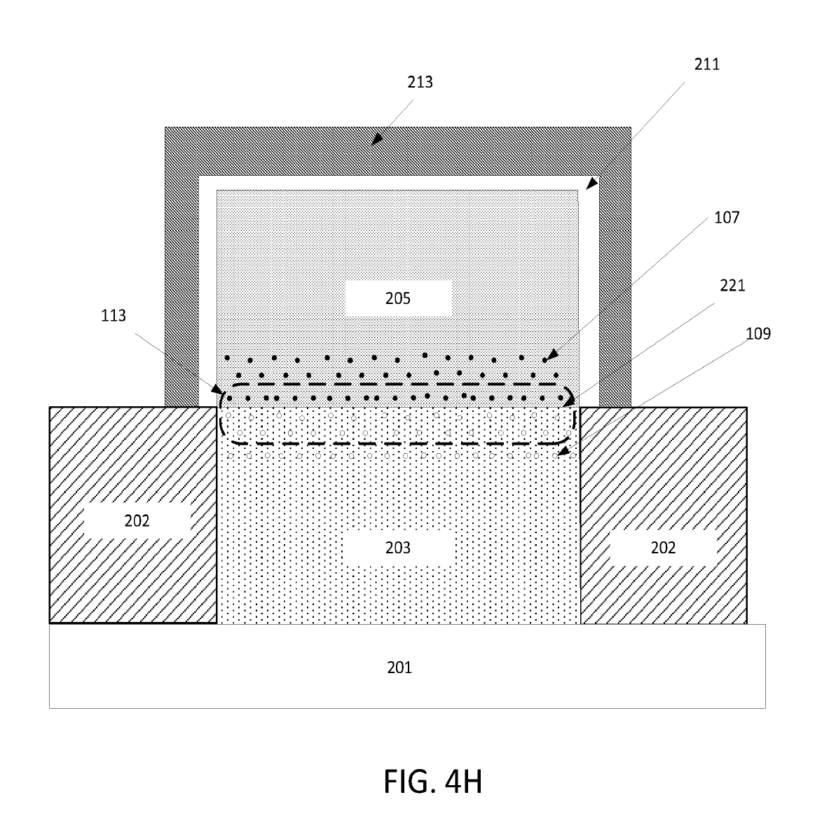

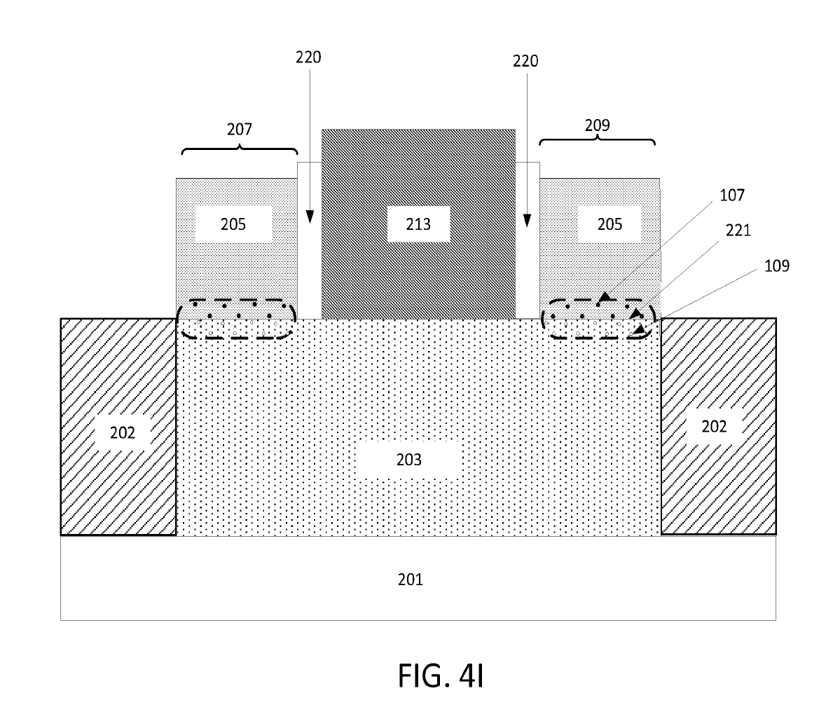

Another aspect of the present disclosure relates to methods of making non-planar semiconductor devices including a diffusion tolerant III-V heterostructure consistent with the present disclosure. In this regard reference is made to FIG. 3, which for the sake of illustration will be described in conjunction with FIGS. 4A-4I. As shown in FIG. 3, method 300 begins at block 301. The method may then proceed to block 302, wherein a substrate including a trench may be provided. This concept is illustrated in FIG. 4A, which depicts a substrate 201 with trench dielectric 202 formed thereon, wherein trenches (not separately labeled) are defined by an upper surface of substrate 201 and trench dielectric 202. It should therefore be understood that in the context of FIG. 4A, substrate 201 and trench dielectric 202 may collectively be considered a “substrate” upon which further layers may be formed. It is also noted that for the sake of clarity and ease of understanding, FIG. 4A depicts an embodiment of a substrate in which one or more seeding layers, transition layers, etc. are not formed within a trench. As such an upper surface of substrate 201 may form a growth surface for the deposition of a layer of first III-V compound semiconductor, as will be described later.

With the foregoing in mind, a substrate including a trench (e.g., as shown in FIG. 4A) may be provided in any suitable manner. In some embodiments, the substrate structure shown in FIG. 4A may be formed by providing a substrate (e.g., of silicon, germanium, etc.) and forming one or more hard mask layers thereon. The hard mask layers may then be processed into one or more hard mask fins. Trench dielectric 202 may then be deposited on the substrate and between/around the hard mask fin(s). Trench dielectric may then be optionally planarized, and the hard mask fins may be removed (e.g., via an etching process) to form one or more trenches consistent with the structure of FIG. 4A, i.e., which includes one or more trenches bounded by an upper surface of substrate 201 and trench sidewalls defined by trench dielectric 202.

In some embodiments the trenches formed on or in substrate 201 are suitable for use in a so-called aspect ratio trapping (ART) process. With this in mind, the height to width ratio of the trenches described herein may vary widely, e.g., from about 2:1, about 4:1, about 6:1, or even about 8:1 or more.

Although FIG. 4A depicts the use of a trench including vertical sidewalls it should be understood that the sidewalls of the trenches described herein may be angled. For example, the sidewalls of the trenches described herein may be formed at an angle ranging from about 85 to about 120 degrees, such as about 85 to 95 degrees, relative to a horizontal plane of substrate 201. In some embodiments, the sidewalls of the trenches described herein are substantially vertical, i.e., are formed at an angle ranging from about 88 to about 92 degrees, relative to the horizontal plane of substrate 201.

Trench dielectric 202 may be deposited in any suitable manner. In some embodiments, trench dielectric 202 (which may be formed from the materials previously described) may be deposited on substrate 201 via chemical vapor deposition (CVD), plasma enhanced CVD (PECVD), or another suitable additive deposition process. Without limitation trench dielectric 202 is in the form of an oxide (e.g., SiO₂) that is deposited on substrate 201 using CVD or PECVD.

Returning to FIG. 3, the method may proceed from block 302 to block 303, pursuant to which a subfin region may be formed in one or more trenches on or within substrate 101. In some embodiments formation of the subfin includes forming one or more layers of a first III-V compound semiconductor within the trench(es). Without limitation, in some embodiments one or more layers of first III-V compound semiconductor (such as the materials noted above for layer 103 and subfin region 203) is/are selectively deposited within a trench, e.g., using CVD, PECVD, MOCVD, atomic layer deposition, or another suitable technique. This concept is illustrated in FIG. 4B, which depicts the formation of subfin region 203 in a trench located at region A of FIG. 64. In this non-limiting example, subfin region 203 is a single layer of a first III-V compound semiconductor, which is selectively formed on substrate 201 and between trench sidewalls defined by trench dielectric 202. As noted above, however, multiple layers of first III-V compound semiconductor(s) as well as layers of other compositions may also be formed.

The layer(s) of first III-V compound semiconductor included in subfin region 203 may be formed in any suitable manner. For example, the layer(s) of first III-V compound semiconductor included in subfin region 203 may be formed using an epitaxial growth technique for the chosen materials, such as but not limited to metal-organic chemical vapor deposition (MOCVD), molecular beam epitaxy (MBE), combinations thereof, and the like. In some embodiments, one or more layers of subfin region 203 may epitaxially grown within a trench, and on (e.g. directly on) an upper surface of substrate 201 or on or more intervening layers deposited thereon. In some embodiments subfin region 203 includes or is formed from one or more layers of a first III/V compound semiconductor selected from AlSb, GaSb, GaAsSb, GaAs, or InAlAs. In any case, all or a portion of the layer(s) forming subfin region 203 may be doped with an amphoteric dopant such as those noted above.

In the embodiment shown in FIGS. 4A-4I, the layer(s) of subfin region 203 are confined to a trench and thus may have sidewalls that are complementary to the trench sidewalls defined by trench dielectric 202 (or one or more trench isolation layers deposited thereon). This concept is shown in FIG. 4B, which illustrates subfin region 203 as being formed from a single layer of first III-V compound semiconductor that has walls that are conformal to the trench sidewalls defined by trench dielectric 202.

Returning to FIG. 3, the method may proceed from block 303 to block 304, wherein a channel region may be formed. Consistent with the foregoing discussion, formation of the channel region may involve the formation of one or more layers of a second III-V compound semiconductor, e.g., on or directly on an upper surface of one or more layers of the first III-V compound semiconductor included in subfin region 203. For the sake of illustration the formation of a channel region including a single layer of a second III-V compound semiconductor will be described. However it should be understood that the channel region may have any suitable structure known in the art. For example the channel region may include at least one high-mobility channel layer, which may be used independently or in the context of a quantum well structure (e.g., two or three epitaxial layers of differing band gaps) that are grown on a seeding surfaced provided by one or more layers of the first III-V compound semiconductor of subfin 203.

With the foregoing in mind, one example process flow that may be used to form the channel is illustrated in FIGS. 4C-E. As shown in FIG. 4C, formation of channel region 205 may initiated by the formation of one or more layers of a second III-V compound semiconductor, such as those described above. Formation of the layers of second III-V compound semiconductor may be achieved in any suitable manner, such as by CVD, MOCVD, MBE, combinations thereof, and the like. Without limitation, the layer(s) of second III-V compound semiconductor are preferably formed by an epitaxial growth technique for the selected materials, such that the layer(s) is/are hetero-epitaxially grown, e.g., on an epitaxial seeding surface provided by an upper surface of one or more of the first III-V compound semiconductor layers included in subfin region 203. In any case, the layer(s) of second III-V compound semiconductor may be selectively deposited on the upper surface of subfin region 203, or (as shown in FIG. 4C), such layers may be bulk deposited over a larger region. In the latter case and as shown in FIG. 4D, the formation of channel region 205 may include a planarization step, which may reduce the height of the layer(s) forming channel region 205 to about the same level as the height of trench dielectric 202.

As may be appreciated, the structure shown in FIG. 4D may be used in various types of semiconductor devices. For example, source and drain regions may be formed in channel region 205 (e.g., by doping portions thereof with an amphoteric dopant) and a gate stack may be formed on an upper surface of channel region 205 of FIG. 4D, e.g. so as to form a single gated transistor. While such devices are useful, for the sake of illustration the present disclosure will go on to describe an example process whereby a non-planar device such as a multigated transistor may be formed.

In this regard, formation of channel region 205 may further involve recessing trench dielectric 202 such that at least a portion of channel region 205 protrudes above an upper surface of trench dielectric 202. This concept is shown in FIG. 4E, which illustrates an embodiment in which trench dielectric 202 is recessed such that channel region 205 extends above an upper surface thereof. Recession of trench dielectric 202 may be accomplished in any suitable manner. In some embodiments for example, trench dielectric 202 may be recessed using a selective dry or wet etching process, such as but not limited to a photochemical etching process.

Although not explicitly shown in FIGS. 4A-4I, formation of channel region 205 in some embodiments involves the formation of source and drain regions, as previously described. In this regard source and drain regions may be formed within channel 205 in any suitable manner. For example, source and drain regions may be formed in channel region 205 by doping one or more regions thereof with an amphoteric dopant, such as those previously described.

Returning to FIG. 3, the method may proceed from block 304 to block 305, pursuant to which a gate stack may be formed. In this regard a gate stack of any suitable structure may be used, and any suitable number of gates may be used. Thus while the present disclosure focuses on embodiments in which a single gate stack of a particular structure is used, it should be understood that such embodiments are for the sake of example only and that other gate structures are envisioned and encompassed by the present disclosure.

With the foregoing in mind reference is made to FIGS. 4F-4I, which depict one example of a process flow that may be used to form a gate stack consistent with the present disclosure. As shown in FIG. 4F, formation of a gate stack may begin with the deposition of a layer of gate dielectric 211, which may isolate all or a portion of the channel region 205 from a gate, as generally understood in the art. A layer 213 of gate electrode material may then be deposited on the gate dielectric, as generally shown in FIG. 4G. Deposition of the layer of gate dielectric 211 and the layer of gate electrode 213 material may be accomplished in any suitable manner, e.g., by a CVD process, MOCVD process, PECVD process, a sputtering process, combinations thereof, and the like. Although the present disclosure envisions embodiments in which the layer 211 of gate dielectric and the layer 213 of gate electrode material are selectively deposited channel region 205, FIGS. 4F and 4G depict an embodiment in which such layers are deposited over a wider area.

In some embodiments, layer 213 of gate electrode material is composed of a metal material, and layer 211 of gate dielectric is composed of a high-K dielectric material. For example in some embodiments the layer 211 of gate dielectric is formed from one or more of hafnium oxide, hafnium oxy-nitride, hafnium silicate, lanthanum oxide, zirconium oxide, tantalum oxide, barium strontium titanate, barium titanate, strontium titanate, yttrium oxide, aluminum oxide, lead scandium tantalum oxide, lead zinc niobate, or a combination thereof. Furthermore a portion of layer 211 of gate dielectric may include a layer of native oxide thereof.

In some embodiments, the layer 213 of gate electrode material is composed of a metal layer such as, but not limited to, one or more layers of a metal nitride, metal carbide, metal silicide, metal aluminide, hafnium, Zirconium, titanium, tantalum, aluminum, ruthenium, palladium, platinum, cobalt, nickel or conductive metal oxides. In a specific non-limiting embodiment, the layer 213 is composed of a non-work function-setting fill material formed above a metal work function-setting layer.

After the layer(s) 211, 213 of gate dielectric and gate electrode are formed (as shown in FIG. 4G), such layers may be processed into a desired geometry, e.g., by a dry or wet etching process or another selective material removal process. A gate spacer 220 may then be formed, e.g., by depositing a conformal layer of gate spacer material and etching the layer to form the desired geometry. These concepts are illustrated in FIGS. 4H and 4I, which depict layers 211, 213 as being patterned to form a gate stack over a portion of channel 205, which is isolated from source and drain regions 207, 209 by spacer 220. As may be appreciated, FIGS. 4H and 4I depict the same structure as shown in FIGS. 2B and 2C. That is, FIGS. 4H and 4I depict the same non-planar semiconductor device 200 that is shown in FIGS. 2B and 2C.

Returning to FIG. 3, once the gate stack has been formed the method may proceed from block 305 to block 306, whereupon the method may end.

It is noted that the foregoing discussion has focused on the development of heterostructures and the use thereof in various non-planar devices. It should be understood that the use of the heterostructures described herein is not limited to non-planar devices, and that they may be employed in any suitable type of device, including planar devices such as planar transistors.

Another aspect of the present disclosure relates to a computing device including one or more non-planar semiconductor devices consistent with the present disclosure. In this regard reference is made to FIG. 5, which illustrates a computing device 500 in accordance with one implementation of the present disclosure. The computing device 500 houses a board 502 (e.g., a motherboard). The board 502 may include a number of components, including but not limited to a processor 504 and at least one communication chip 506. The processor 504 is physically and electrically coupled to the board 502. In some implementations the at least one communication chip 506 is also physically and electrically coupled to the board 502. In further implementations, the communication chip 506 is part of the processor 504.

Depending on its applications, computing device 500 may include other components that may or may not be physically and electrically coupled to the board 502. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 506 enables wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing device 500 includes an integrated circuit die packaged within the processor 504. In some implementations of the present disclosure, the integrated circuit die of the processor includes one or more devices, such as MOSFET and/or non-planar transistors built in accordance with implementations of the present disclosure. The term “processor” may refer to any device or portion of a device that processes electronic data from registers and/or memory to transform that electronic data into other electronic data that may be stored in registers and/or memory.

The communication chip 506 also includes an integrated circuit die packaged within the communication chip 506. In accordance with another implementation of the present disclosure, the integrated circuit die of the communication chip includes one or more devices, such as MOSFET and/or non-planar transistors built in accordance with implementations of the present disclosure.

In further implementations, another component housed within the computing device 500 may contain an integrated circuit die that includes one or more devices, such as MOSFET and/or non-planar transistors built in accordance with implementations of the present disclosure.

In various implementations, the computing device 500 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 500 may be any other electronic device that processes data.

### EXAMPLES

The following examples enumerate additional embodiments of the present disclosure.

### Example 1

According to this example there is provided a semiconductor device including a III-V semiconductor heterostructure, the III-V semiconductor heterostructure including: a first layer of a first III-V semiconductor compound formed on a substrate, the first layer having a first band gap; a second layer of a second III-V semiconductor compound formed on the first layer to define an n-p junction therebetween, the second layer having a second band gap that differs from the first band gap; wherein: at least a portion of the first layer, the second layer, or a combination of the first and second layers is doped with an amphoteric dopant; when the amphoteric dopant is a donor in the first layer, it is an acceptor in the second layer; and when the amphoteric dopant is an acceptor in the first layer, it is a donor in the second layer.

### Example 2

This example includes any or all of the features of example 1, wherein the first III-V semiconductor compound is selected from the group consisting of AlSb, GaSb, GaAlSb, GaAsSb, InAlAs, or a combination thereof.

### Example 3

This example includes any or all of the features of example 2, wherein the first III-V semiconductor compound is a p-type semiconductor.

### Example 4

This example includes any or all of the features of example 1, wherein the second III-V semiconductor compound is selected from the group consisting of InGaAs, InAs, InSb, or a combination thereof.

### Example 5

This example includes any or all of the features of example 4, wherein the second III-V semiconductor compound is an n-type semiconductor.

### Example 6

This example includes any or all of the features of example 1, wherein the amphoteric dopant is selected from the group consisting of C, Si, Ge, and Sn.

### Example 7

This example includes any or all of the features of example 1, wherein: the first III-V semiconductor compound is a p-type semiconductor selected from the group consisting of AlSb, GaSb, GaAlSb, GaAsSb, InAlAs, or a combination thereof; the second III-V semiconductor compound is an n-type semiconductor selected from the group consisting of InGaAs, InAs, InSb, or a combination thereof; and the amphoteric dopant is selected from the group consisting of C, Si, Ge, and Sn.

### Example 8

This example includes any or all of the features of example 7, wherein: the first III-V semiconductor compound is formed from p-type GaSb or GaAsSb; the second III-V semiconductor compound is formed from n-type InGaAs or InAs; and the second layer is doped with the amphoteric dopant.

### Example 9

This example includes any or all of the features of example 8, wherein the amphoteric dopant is Si.

### Example 10

This example includes any or all of the features of example 7, wherein: the first III-V semiconductor compound is formed from p-type InAlAs; the second III-V semiconductor compound is formed from n-type InGaAs; and the second layer is doped with the amphoteric dopant.

### Example 11

This example includes any or all of the features of example 9, wherein the amphoteric dopant is C.

### Example 12

This example includes any or all of the features of example 7, wherein: the first III-V semiconductor compound is formed from P-type GaSb, AlSb, or GaAlSb; the second III-V semiconductor compound is formed from n-type InSb or InAs; and the second layer is doped with the amphoteric dopant.

### Example 13

This example includes any or all of the features of example 9, wherein the amphoteric dopant is Si, C or Sn.

### Example 14

This example includes any or all of the features of example 1, further including a trench defined by at least two trench sidewalls, wherein: the first layer is disposed within the trench to form a subfin region; the second layer is formed directly on the first layer; a portion of the second layer is doped with the amphoteric dopant to form a source; and a portion of the second layer is doped with the amphoteric dopant to form a drain.

### Example 15

This example includes any or all of the features of example 14, further including a gate stack on at least a portion of the second layer.

### Example 16

This example includes any or all of the features of example 15, wherein the gate stack includes a layer of gate dielectric on the second layer, and a gate electrode formed on the layer of gate dielectric.

### Example 17

This example includes any or all of the features of example 16, wherein the semiconductor device is a single gate transistor or a multi-gate transistor.

### Example 18

This example includes any or all of the features of example 16, wherein the semiconductor device is a fin based field effect transistor.

### Example 19

This example includes any or all of the features of example 14, wherein the trench sidewalls comprise a dielectric oxide.

### Example 20

This example includes any or all of the features of example 19, wherein the first layer is in contact with the dielectric oxide.

### Example 21

This example includes any or all of the features of example 16, wherein: at least a portion of the second layer protrudes above an upper surface of the trench sidewalls to form an exposed portion of the second layer, the exposed portion including an upper surface and at least first and second sides; and; the gate electrode is disposed on the upper surface and at least one of the first and second sides of the exposed portion.

### Example 22

This example includes any or all of the features of example 21, wherein the gate electrode is disposed on the upper surface and the both the first and second sides of the exposed portion.

### Example 23

According to this example there is provided a method of making a semiconductor device, including: providing a substrate; forming a first layer of a first III-V semiconductor compound formed on the substrate, the first layer having a first band gap; forming a second layer of a second III-V semiconductor compound on the first layer to define an n-p junction therebetween, the second layer having a second band gap that differs from the first band gap; wherein: at least a portion of the first layer, the second layer, or a combination of the first and second layers is doped with an amphoteric dopant; when the amphoteric dopant is a donor in the first layer, it is an acceptor in the second layer; and when the amphoteric dopant is an acceptor in the first layer, it is a donor in the second layer.

### Example 24

This example includes any or all of the features of example 23, wherein the first III-V semiconductor compound is selected from the group consisting of AlSb, GaSb, GaAlSb, GaAsSb, InAlAs, or a combination thereof.

### Example 25

This example includes any or all of the features of example 24, wherein the first III-V semiconductor compound is a p-type semiconductor.

### Example 26

This example includes any or all of the features of example 23, wherein the second III-V semiconductor compound is selected from the group consisting of InGaAs, InAs, InSb, or a combination thereof.

### Example 27

This example includes any or all of the features of example 26, wherein the second III-V semiconductor compound is an n-type compound.

### Example 28

This example includes any or all of the features of example 23, wherein the amphoteric dopant is selected from the group consisting of C, Si, Ge, and Sn.

### Example 29

This example includes any or all of the features of example 23, wherein: the first III-V semiconductor compound is a p-type semiconductor selected from the group consisting of AlSb, GaSb, GaAlSb, GaAsSb, InAlAs, or a combination thereof; the second III-V semiconductor compound is an n-type semiconductor selected from the group consisting of InGaAs, InAs, InSb, or a combination thereof; and the amphoteric dopant is selected from the group consisting of C, Si, Ge, and Sn.

### Example 30

This example includes any or all of the features of example 29, wherein: the first III-V semiconductor compound is formed from p-type GaSb or GaAsSb; the second III-V semiconductor compound is formed from n-type InGaAs or InAs; and the second layer is doped with the amphoteric dopant.

### Example 31

This example includes any or all of the features of example 30, wherein the amphoteric dopant is Si.

### Example 32

This example includes any or all of the features of example 30, wherein: the first III-V semiconductor compound is formed from p-type InAlAs; the second III-V semiconductor compound is formed from n-type InGaAs; and the second layer is doped with the amphoteric dopant.

### Example 33

This example includes any or all of the features of example 32, wherein the amphoteric dopant is C.

### Example 34

This example includes any or all of the features of example 30, wherein: the first III-V semiconductor compound is formed from p-type GaSb, AlSb, or GaAlSb; the second III-V semiconductor compound is formed from n-type InSb or InAs; and the second layer is doped with the amphoteric dopant.

### Example 35

This example includes any or all of the features of example 34, wherein the amphoteric dopant is Si, C or Sn.

### Example 36

This example includes any or all of the features of example 23, wherein: forming the first layer includes depositing the first layer within a trench to form a subfin region of the semiconductor device; forming the second layer includes depositing the second layer directly on the first layer; a portion of the second layer is doped with the amphoteric dopant to form a source; and a portion of the second layer is doped with the amphoteric dopant to form a drain.

### Example 37

This example includes any or all of the features of example 36, further including forming a gate stack on at least a portion of the second layer.

### Example 38

This example includes any or all of the features of example 37, wherein forming the gate stack includes forming a layer of gate dielectric on the second layer, and forming a gate electrode on the layer of gate dielectric.

### Example 39

This example includes any or all of the features of example 38, wherein the semiconductor device is a single gate transistor or a multi-gate transistor.

### Example 40

This example includes any or all of the features of example 38, wherein the semiconductor device is a fin based field effect transistor.

### Example 41

This example includes any or all of the features of example 36, wherein the trench includes trench sidewalls, the trench sidewalls including a dielectric oxide.

### Example 42

This example includes any or all of the features of example 41, wherein the first layer is in contact with the dielectric oxide.

### Example 43

This example includes any or all of the features of example 36, wherein: the trench includes trench sidewalls; at least a portion of the second layer protrudes above an upper surface of the trench sidewalls to form an exposed portion of the second layer, the exposed portion including an upper surface and at least first and second sides; and the gate electrode is disposed on the upper surface and at least one of the first and second sides of the exposed portion.

### Example 44

This example includes any or all of the features of example 23, wherein the gate electrode is disposed on the upper surface and the both the first and second sides of the exposed portion.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and embodiments have been described herein. The features, aspects, and embodiments are susceptible to combination with one another as well as to variation and modification, as will be understood by those having skill in the art. The present disclosure should, therefore, be considered to encompass such combinations, variations, and modifications.

What is claimed is:

1. A semiconductor device comprising a III-V semiconductor heterostructure, the III-V semiconductor heterostructure comprising:
a first layer of a first III-V semiconductor compound formed on a substrate, the first layer having a first band gap;
a second layer of a second III-V semiconductor compound formed on the first layer to define an n-p junction therebetween, the second layer having a second band gap that differs from the first band gap;
wherein:
at least a portion of the first layer, the second layer, or a combination of the first and second layers is doped with an amphoteric dopant;
when the amphoteric dopant is a donor in said first layer, it is an acceptor in said second layer; and
when the amphoteric dopant is an acceptor in said first layer, it is a donor in said second layer.

2. The semiconductor device of claim 1, wherein said first III-V semiconductor compound is p-type semiconductor and is selected from the group consisting of AlSb, GaSb, GaAlSb, GaAsSb, InAlAs, or a combination thereof.

3. The semiconductor device of claim 1, wherein said second III-V semiconductor compound is an n-type semiconductor and is selected from the group consisting of InGaAs, InAs, InSb, or a combination thereof.

4. The semiconductor device of claim 1, wherein said amphoteric dopant is selected from the group consisting of C, Si, Ge, and Sn.

5. The semiconductor device of claim 1, wherein:
said first III-V semiconductor compound is a p-type semiconductor selected from the group consisting of AlSb, GaSb, GaAlSb, GaAsSb, InAlAs, or a combination thereof;
said second III-V semiconductor compound is an n-type semiconductor selected from the group consisting of InGaAs, InAs, InSb, or a combination thereof; and
said amphoteric dopant is selected from the group consisting of C, Si, Ge, and Sn.

6. The semiconductor device of claim 5, wherein:
said first III-V semiconductor compound is formed from p-type GaSb or GaAsSb;
said second III-V semiconductor compound is formed from n-type InGaAs or InAs; and
said second layer is doped with said amphoteric dopant.

7. The semiconductor device of claim 5, wherein:
said first III-V semiconductor compound is formed from p-type InAlAs;
said second III-V semiconductor compound is formed from n-type InGaAs; and
said second layer is doped with said amphoteric dopant.

8. The semiconductor device of claim 5, wherein:
said first III-V semiconductor compound is formed from P-type GaSb, AlSb, or GaAlSb;
said second III-V semiconductor compound is formed from n-type InSb or InAs; and
said second layer is doped with said amphoteric dopant.

9. The semiconductor device of claim 1, further comprising a trench defined by at least two trench sidewalls, wherein:
said first layer is disposed within said trench to form a subfin region;
said second layer is formed directly on said first layer;
a portion of said second layer is doped with said amphoteric dopant to form a source; and
a portion of said second layer is doped with said amphoteric dopant to form a drain.

10. The semiconductor device of claim 9, further comprising a gate stack on at least a portion of said second layer, wherein said gate stack comprises a layer of gate dielectric on said second layer, and a gate electrode is formed on the layer of gate dielectric.

11. The semiconductor device of claim 10, wherein said trench sidewalls comprise a dielectric oxide, and said first layer is in contact with said dielectric oxide.

12. The semiconductor device of claim 9, wherein:
at least a portion of said second layer protrudes above an upper surface of said trench sidewalls to form an exposed portion of said second layer, the exposed portion comprising an upper surface and at least first and second sides; and;
said gate electrode is disposed on the upper surface and at least one of the first and second sides of the exposed portion.

13. A method of making a semiconductor device, comprising:
providing a substrate;
forming a first layer of a first III-V semiconductor compound formed on the substrate, the first layer having a first band gap;
forming a second layer of a second III-V semiconductor compound on the first layer to define an n-p junction therebetween, the second layer having a second band gap that differs from the first band gap;
wherein:
at least a portion of the first layer, the second layer, or a combination of the first and second layers is doped with an amphoteric dopant;
when the amphoteric dopant is a donor in said first layer, it is an acceptor in said second layer; and
when the amphoteric dopant is an acceptor in said first layer, it is a donor in said second layer.

14. The method of claim 13, wherein said first III-V semiconductor compound is a p-type semiconductor and is selected from the group consisting of AlSb, GaSb, GaAlSb, GaAsSb, InAlAs, or a combination thereof.

15. The method of claim 13, wherein said second III-V semiconductor compound is an n-type semiconductor and is selected from the group consisting of InGaAs, InAs, InSb, or a combination thereof.

16. The method of claim 13, wherein said amphoteric dopant is selected from the group consisting of C, Si, Ge, and Sn.

17. The method of claim 13, wherein:
said first III-V semiconductor compound is a p-type semiconductor selected from the group consisting of AlSb, GaSb, GaAlSb, GaAsSb, InAlAs, or a combination thereof;
said second III-V semiconductor compound is an n-type semiconductor selected from the group consisting of InGaAs, InAs, InSb, or a combination thereof; and
said amphoteric dopant is selected from the group consisting of C, Si, Ge, and Sn.

18. The method of claim 17, wherein
said first III-V semiconductor compound is formed from p-type GaSb or GaAsSb;
said second III-V semiconductor compound is formed from n-type InGaAs or InAs; and
said second layer is doped with said amphoteric dopant.

19. The method of claim 17, wherein:
said first III-V semiconductor compound is formed from p-type InAlAs;
said second III-V semiconductor compound is formed from n-type InGaAs; and
said second layer is doped with said amphoteric dopant.

20. The method of claim 17, wherein:
said first III-V semiconductor compound is formed from p-type GaSb, AlSb, or GaAlSb;
said second III-V semiconductor compound is formed from n-type InSb or InAs; and
said second layer is doped with said amphoteric dopant.

21. The method of claim 13, wherein:
forming said first layer comprises depositing said first layer within a trench to form a subfin region of said semiconductor device;
forming said second layer comprises depositing said second layer directly on said first layer;
a portion of said second layer is doped with said amphoteric dopant to form a source; and
a portion of said second layer is doped with said amphoteric dopant to form a drain.

22. The method of claim 21, further comprising forming a gate stack on at least a portion of said second layer, wherein said gate stack comprises a layer of gate dielectric on said second layer, and a gate electrode is formed on the layer of gate dielectric.

23. The method of claim 22, wherein said semiconductor device is a single gate transistor or a multi-gate transistor.

24. The method of claim 21, wherein said trench comprises trench sidewalls, said trench sidewalls comprising a dielectric oxide and said first layer is in contact with said dielectric oxide.

25. The method of claim 21, wherein:
said trench comprises trench sidewalls;
at least a portion of said second layer protrudes above an upper surface of said trench sidewalls to form an exposed portion of said second layer, the exposed portion comprising an upper surface and at least first and second sides; and
said gate electrode is disposed on the upper surface and at least one of the first and second sides of the exposed portion.
